(19) United States
(12) Patent Application Publication
(10) Pub. No.: US 2005/0110127 A1
(43) Pub. Date: May 26, 2005

(54) Semiconductor device

(75) Inventors: Kouichi Kanemoto, Higashiyamato (JP); Kazunari Suzuki, Tokyo (JP); Toshihiro Shiotsuki, Higashiyamato (JP); Hideyuki Suga, Hamura (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 10/981,489

(22) Filed: Nov. 5, 2004

(30) Foreign Application Priority Data
Nov. 20, 2003 (JP) 2003-390029

(51) Int. Cl. H01L 29/423

(52) U.S. Cl. 257/686

(57) ABSTRACT

A thin semiconductor device which assures a high production yield. The semiconductor device includes: first and second semiconductor chips each of which has electrodes over its first surface; first leads electrically connected with the electrodes of the first semiconductor chip through first bonding wires; second leads electrically connected with the electrodes of the second semiconductor chip through second bonding wires; a die pad with first and second surfaces opposite each other where the first semiconductor chip's first surface is bonded to the first surface and the second semiconductor chip's first surface is bonded to the second surface; and a resin sealer which seals the first and second semiconductor chips, inner portions of the first and second leads, the first and second bonding wires, and the die pad. The inner portions of the first and second leads and the die pad lie at the same height level in a thickness direction of the resin sealer.

### CROSS-REFERENCE TO RELATED APPLICATION

The present application claims priority from Japanese patent application No. 2003-390029 filed on Sep. 20, 2003, the content of which is hereby incorporated by reference into this application.

### BACKGROUND OF THE INVENTION

The present invention relates to a semiconductor device and technology for manufacturing the same and more particularly to technology which is effective for a semiconductor device with two stacked semiconductor chips sealed by one resin sealer.

A semiconductor device which is manufactured by stacking two semiconductor chips with memory circuitry and sealing them by one resin sealer is known as one which meets the demand for a larger memory capacity. For this type of semiconductor device, a variety of package structures have been proposed and commercialized. For example, International Publication WO 00/22676 (Patent Reference 1) discloses a TSOP (Thin Small Outline Package) semiconductor device which is suitable as a thin model.

The TSOP semiconductor device disclosed in the Patent Reference 1 includes: a first and a second semiconductor chip each having plural electrodes (bonding pads) arranged along a first side of a main surface (circuit formation surface) ; plural first leads arranged along the first side of the first semiconductor chip, each having an inner and an outer portion; plural second leads arranged along a second side, opposite to the first side of the first semiconductor chip, each having an inner and an outer portion; plural first bonding wires which electrically connect the plural electrodes of the first semiconductor chip and the plural first leads respectively; plural second bonding wires which electrically connect the plural electrodes of the second semiconductor chip and the plural second leads respectively; a support lead which supports the first and second semiconductor chips; and a resin sealer which seals the first and second semiconductor chips, the first and second leads, the first and second bonding wires and the support lead. Here, the reverse surfaces of the first and second semiconductor chips face each other so that the first side of the first semiconductor chip and the second side (opposite to the first side) of the second semiconductor chip are located near the first leads. The first and second semiconductor chips are bonded in a staggered manner that the first side of the first semiconductor chip is located more outward than the second side of the second semiconductor chip, and the first side of the second semiconductor chip is located more outward than the second side of the first semiconductor chip. The support lead is bonded to the main surface of the first or second semiconductor chip.

### SUMMARY OF THE INVENTION

With the trend towards thinner and smaller electronic equipment, there is a growing demand for thinner semiconductor devices, particularly for use in cards. With this background, the inventors have made efforts to develop technology which realizes a thinner TSOP semiconductor device than the abovementioned one. FIG. 21 is a schematic sectional view showing the internal structure of the semiconductor device conceived by the inventors in such efforts.

As shown in FIG. 21, the semiconductor device conceived by the inventors includes:
a first and a second semiconductor chip (2, 3) each having plural electrodes (bonding pads) 4 arranged along a first side (2a, 3a) of their main surface (2x, 3x);
plural first leads 5a arranged along the first side 2a of the first semiconductor chip 2, each having an inner and an outer portion;
plural second leads 5b arranged along a second side 2b, opposite to the first side 2a of the first semiconductor chip 2, each having an inner and an outer portion;
plural first bonding wires 7a which electrically connect the plural electrodes 4 of the first semiconductor chip 2 and the plural first leads 5a respectively;
plural second bonding wires 7b which electrically connect the plural electrodes 4 of the second semiconductor chip 3 and the plural second leads 5b respectively;
a die pad (also called a tab or chip mounting area) 6 with a first surface 6x and a second surface 6y opposite each other, which bears the first and second semiconductor chips (2, 3); and
a resin sealer 8 which seals the first and second semiconductor chips (2, 3), inner portions of the first and second leads (5a, 5b), the first and second bonding wires (7a, 7b) and the die pad 6.

The first and second semiconductor chips (2, 3) are bonded by means of an adhesive agent 9 in a staggered manner that their main surfaces (2x, 3x) face each other with the first side 2a of the first semiconductor chip 2 and the second side 3b (opposite to the first side 3a) of the second semiconductor chip 3 being located near the first leads 5a, and the first side 2a of the first semiconductor chip 2 being located more outward than the second side 3b of the second semiconductor chip 3 and the first side 3a of the second semiconductor chip 3 being located more outward than the second side 2b of the first semiconductor chip 2.

The die pad 6 is bonded to the reverse surface 2y of the first semiconductor chip 2 or the reverse surface 3y of the second semiconductor chip 3 by means of the adhesive agent 9 (in the case of FIG. 21, the first surface 6x of the die pad 6 is bonded to the reverse surface of the second semiconductor chip 3).

In this package structure, the loop height of the first bonding wires 7a is absorbed by the thicknesses of two adhesive agent coatings 9, the second semiconductor chip 3 and the die pad 6; and the loop height of the second bonding wires 7b is absorbed by the thicknesses of one adhesive agent coating 9 and the first semiconductor chip 2. This means that the thickness of the resin sealer 8 over the reverse surface 2y of the first semiconductor chip 2 and over the reverse surface 3y of the second semiconductor chip 3 can be reduced and the overall semiconductor device thickness can be thus reduced.

However, in the above package structure, the following problem arises.

As the resin sealer 8 becomes thinner, the resin thickness over and under the inner portions of the leads 5 (5a, 5b) in the thickness direction also becomes smaller; so taking the fastening strength of the leads 5 into consideration, it is desirable that the inner portions of the leads 5 lie in the center of the thickness of the resin sealer 8 and the outer portions of the leads 5 protrude from the center of the thickness of the resin sealer 8. On the other hand, when the resin sealer 8 is formed by transfer molding, because voids should be reduced in order to prevent an unfavorable influence on the quality of the resin sealer 8, it is desirable that a laminate which includes the two semiconductor chips (2, 3), two adhesive agent coatings 9, and die pad 6 are resin-sealed with the center of the thickness of the laminate coincident with the center of the thickness of the mold die cavity, namely coincident with the center of the thickness of the resin sealer 8. When the fastening strength of the leads 5 and the need for reduction of voids are taken into consideration as mentioned above, the height level of the die pad 6 and that of the inner portions of the leads 5 should be different, or they should be offset from each other in the thickness direction of the resin sealer 8. Such offset between the die pad 6 and the inner portions of the leads 5 is made by bending suspender leads connected with the die pad 6.

However, if the suspender leads connected with the die pad 6 are bent, the strength of the suspender leads may deteriorate and the die pad 6 may become unstable due to movement of resin injected into the mold die cavity. This leads to the possibility that the bonding wires 7b, die pad 6, semiconductor chip 2 and so on are exposed or not covered by the resin sealer 8 (location trouble) Particularly when the semiconductor device should be thin, the resin thickness over and under the laminate should be small; hence, this kind of location trouble might lower the semiconductor device production yield.

An object of the present invention is to provide a thin semiconductor device which assures a high production yield.

The above and further objects and novel features of the invention will more fully appear from the following detailed description and accompanying drawings.

Typical aspects of the invention will be briefly outlined below.

According to one aspect of the invention, a semiconductor chip (Type A) includes:
first and second semiconductor chips each having first and second surfaces opposite each other and a plurality of electrodes arranged over the first surface;
a plurality of first leads each having an inner portion and an outer portion, the inner portions being electrically connected with the plural electrodes of the first semiconductor chip through a plurality of first bonding wires respectively;
a plurality of second leads each having an inner portion and an outer portion, the inner portions being electrically connected with the plural electrodes of the second semiconductor chip through a plurality of second bonding wires respectively;
a die pad having first and second surfaces opposite each other, the first semiconductor chip's first surface being bonded to the first surface and the second semiconductor chip's first surface being bonded to the second surface; and
a resin sealer which seals the first and second semiconductor chips, the inner portions of the plural first and second leads, the plural first and second bonding wires, and the die pad,
wherein the inner portions of the plural first and second leads and the die pad lie at the same height level in a thickness direction of the resin sealer.

According to another aspect of the invention, in the semiconductor device of Type A, a center of a thickness of each of the inner portions of the first and second leads lies within a thickness of the die pad.

According to another aspect of the invention, in the semiconductor device of Type A, the inner portions of the first and second leads and the die pad lie in a center of a thickness of the resin sealer.

According to another aspect of the invention, in the semiconductor device of Type A, the center of the thickness of the resin sealer lies within the thickness of each of the inner portions of the first and second leads and the die pad.

According to another aspect of the invention, the semiconductor device of Type A further has a suspender lead integral with the die pad, wherein the suspender lead is straight or not bent in the thickness direction of the resin sealer and lies at the same height level as the inner portions of the first and second leads in the thickness direction of the resin sealer.

According to another aspect of the invention, in the semiconductor device of Type A,
a loop height of the first bonding wires is lower than a second surface of the first semiconductor chip in the thickness direction of the resin sealer; and
a loop height of the second bonding wires is lower than a second surface of the second semiconductor chip in the thickness direction of the resin sealer.

According to another aspect of the invention, in the semiconductor device of Type A,
the first and the second semiconductor chips each have first and second sides opposite each other;
the plural electrodes of the first semiconductor chip are arranged along the first side of the first semiconductor chip;
the plural electrodes of the second semiconductor chip are arranged along the first side of the second semiconductor chip;
the plural first leads are arranged along the first side of the first semiconductor chip;
the plural second leads are arranged along the second side of the first semiconductor chip; and
the first and second semiconductor chips are bonded to the die pad in a staggered manner that their first surfaces face each other with the first side of the first semiconductor chip and the second side of the second semiconductor chip being located near the first leads, the plural electrodes of the first semiconductor chip being located more outward than the second side of the second semiconductor chip and the plural electrodes of the second semiconductor chip being located more outward than the second side of the first semiconductor chip.

According to another aspect of the invention, a semiconductor device (Type B) includes:
first and second semiconductor chips each having first and second surfaces opposite each other and a plurality of electrodes arranged over the first surface;
a plurality of first leads each having an inner portion and an outer portion, the inner portions being electrically connected with the plural electrodes of the first semiconductor chip through a plurality of first bonding wires respectively;
a plurality of second leads each having an inner portion and an outer portion, the inner portions being electrically connected with the plural electrodes of the second semiconductor chip through a plurality of second bonding wires respectively;
a die pad having first and second surfaces opposite each other, the first semiconductor chip's first surface being bonded to the first surface and the second semiconductor chip's first surface being bonded to the second surface; and
a resin sealer which seals the first and second semiconductor chips, the inner portions of the plural first and second leads, the plural first and second bonding wires, and the die pad,
wherein the die pad is larger than an overlapping area in which the first semiconductor chip and the second semiconductor chip overlap.

According to another aspect of the invention, in the semiconductor device of Type B,
the first and the second semiconductor chips each have first and second sides opposite each other;
the plural electrodes of the first semiconductor chip are arranged along the first side of the first semiconductor chip;
the plural electrodes of the second semiconductor chip are arranged along the first side of the second semiconductor chip;
the plural first leads are arranged along the first side of the first semiconductor chip;
the plural second leads are arranged along the second side of the first semiconductor chip; and
the first and second semiconductor chips are bonded to the die pad in a staggered manner that their first surfaces face each other with the first side of the first semiconductor chip and the second side of the second semiconductor chip being located near the first leads, the plural electrodes of the first semiconductor chip being located more outward than the second side of the second semiconductor chip and the plural electrodes of the second semiconductor chip being located more outward than the second side of the first semiconductor chip.

According to another aspect of the invention, a method of manufacturing a semiconductor device includes the steps of:
preparing a lead frame including a die pad having a first surface and a second surface opposite each other and a first side and a second side opposite each other, a plurality of first leads arranged along the first side of the die pad, and a plurality of second leads arranged along the second side of the die pad, the plural first and second leads and the die pad lying at the same height level in their thickness direction, and further preparing first and second semiconductor chips each having a first surface and a second surface opposite each other and a plurality of electrodes arranged over the first surface;
bonding a first surface of the first semiconductor chip to the first surface of the die pad;
bonding a first surface of the second semiconductor chip to the second surface of the die pad;
electrically connecting the plural electrodes of the first semiconductor chip with the inner portions of the plural first leads through a plurality of first bonding wires respectively;
electrically connecting the plural electrodes of the second semiconductor chip with the inner portions of the plural second leads through a plurality of second bonding wires respectively; and
resin-sealing the first and second semiconductor chips, the inner portions of the plural first and second leads, and the plural first and second bonding wires.

According to another aspect of the invention, in the above method of manufacturing a semiconductor device, the first and the second semiconductor chips each have first side and second sides opposite each other;
the plural electrodes of the first semiconductor chip are arranged along the first side of the first semiconductor chip;
the plural electrodes of the second semiconductor chip are arranged along the first side of the second semiconductor chip; and
the first and second semiconductor chips are bonded to the die pad in a staggered manner that their first surfaces face each other with the first side of the first semiconductor chip and the second side of the second semiconductor chip being located near the first leads, the plural electrodes of the first semiconductor chip being located more outward than the second side of the second semiconductor chip and the plural electrodes of the second semiconductor chip being located more outward than the second side of the first semiconductor chip.

Main advantageous effects which are brought about by the invention are: reduction in semiconductor device thickness and improvement in semiconductor device production yield.

### BRIEF DESCRIPTION OF THE DRAWINGS

The invention will be more particularly described with reference to the accompanying drawings, in which:

FIG. 1 is a schematic plan view (top view) showing the external structure of a semiconductor device according to a first embodiment of the present invention;

FIG. 2 is a schematic plan view (top view) showing the internal structure of the semiconductor device according to the first embodiment of the present invention;

FIG. 3 is a schematic bottom view showing the internal structure of the semiconductor device according to the first embodiment of the present invention;

FIG. 4 is a schematic sectional view taken along the x direction of the semiconductor device according to the first embodiment of the present invention;

FIG. 5 shows the dimensions of various parts of what is shown in FIG. 4;

FIG. 6 is a schematic sectional view taken along the y direction of the semiconductor device according to the first embodiment of the present invention;

FIG. 7 is a schematic enlarged sectional view of part (the left half) of what is shown in FIG. 4;

FIG. 8 is a schematic enlarged sectional view of part (the right half) of what is shown in FIG. 4;

FIG. 9 is a schematic plan view showing the internal structure of FIG. 2 in a partially omitted form;

FIG. 10 is a schematic plan view showing the relation between an overlapping area of two semiconductor chips and a die pad in the semiconductor device according to the first embodiment of the present invention;

FIG. 11 is a schematic plan view showing the relation between an overlapping area of two semiconductor chips and a die pad in the semiconductor device according to the first embodiment of the present invention;

FIG. 12 is a fragmentary schematic plan view showing a lead frame used in the manufacture of the semiconductor device according to the first embodiment of the present invention;

FIG. 13 is a schematic enlarged plan view of part of what is shown in FIG. 11;

FIGS. 14(a) and 14(b) are schematic sectional views showing a die bonding process in the manufacture of the semiconductor device according to the first embodiment of the present invention, in which FIG. 14(a) shows a first die bonding step and FIG. 14(b) shows a second die bonding step;

FIGS. 15(a) and 14(b) are schematic sectional views showing a wire bonding process in the manufacture of the semiconductor device according to the first embodiment of the present invention, in which FIG. 15(a) shows a first wire bonding step and FIG. 15(b) shows a second wire bonding step;

FIG. 16 is a schematic sectional view (taken along the x direction) showing a lead frame in place in a mold die in the molding process in the manufacture of the semiconductor device according to the first embodiment of the present invention;

FIG. 17 is a schematic sectional view (taken along the y direction) showing a lead frame in place in a mold die in the molding process in the manufacture of the semiconductor device according to the first embodiment of the present invention;

FIG. 18 is a schematic sectional view showing resin injected in a mold die cavity (formed resin sealer) in the molding process in the manufacture of the semiconductor device according to the first embodiment of the present invention;

FIG. 19 is a schematic plan view (top view) showing the internal structure of a semiconductor device according to a second embodiment of the present invention;

FIG. 20 is a schematic bottom view showing the internal structure of the semiconductor device according to the second embodiment of the present invention; and

FIG. 21 is a schematic sectional view showing the internal structure of the semiconductor device conceived by the inventors.

### DETAILED DESCRIPTION OF THE PREFERRED EMBODIMENTS

Next, preferred embodiments of the present invention will be described in detail referring to the accompanying drawings. In all the drawings that illustrate preferred embodiments of the invention, elements with like functions are designated by like reference numerals and their descriptions are not repeated.

### First Embodiment

The first embodiment concerns a TSOP semiconductor device to which the present invention is applied. TSOP semiconductor devices are available in two types: Type 1 (leads arranged along the long side of the resin sealer) and Type 2 (leads arranged along the short side of the resin sealer). This embodiment is of Type 1.

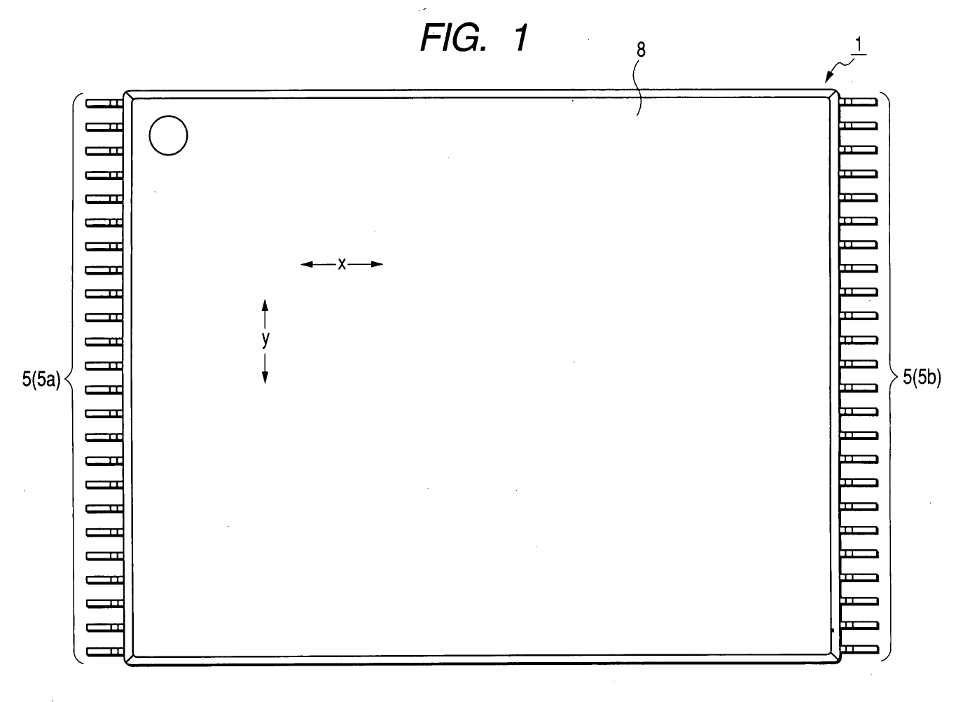

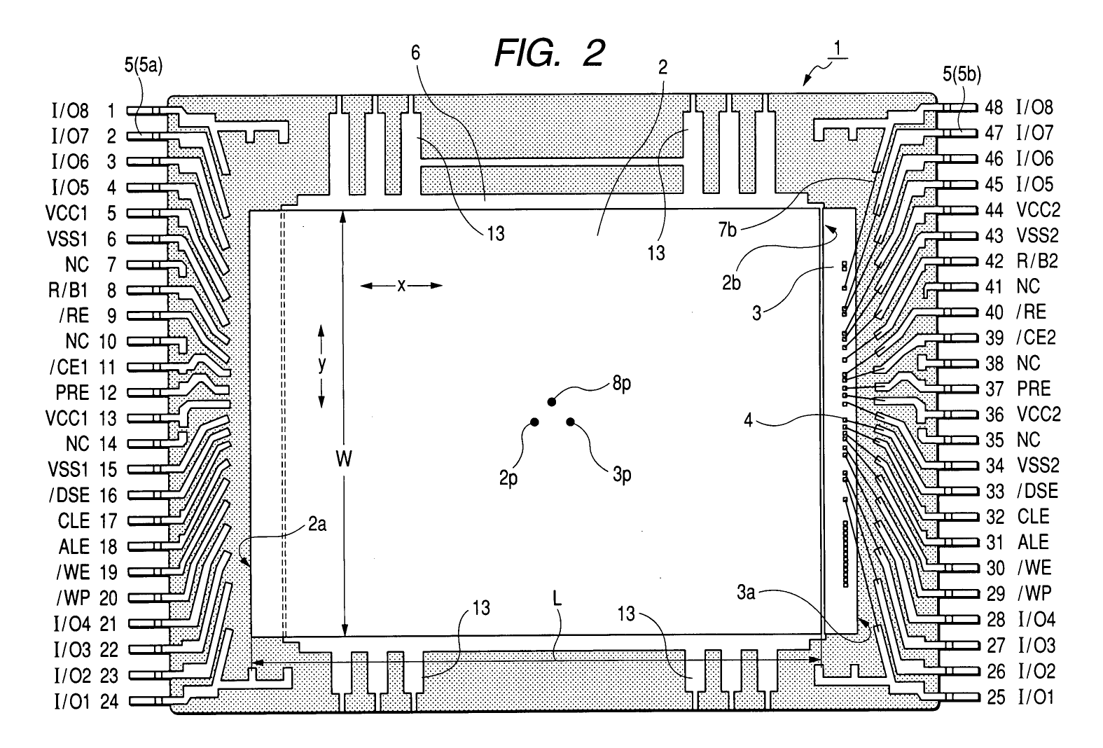

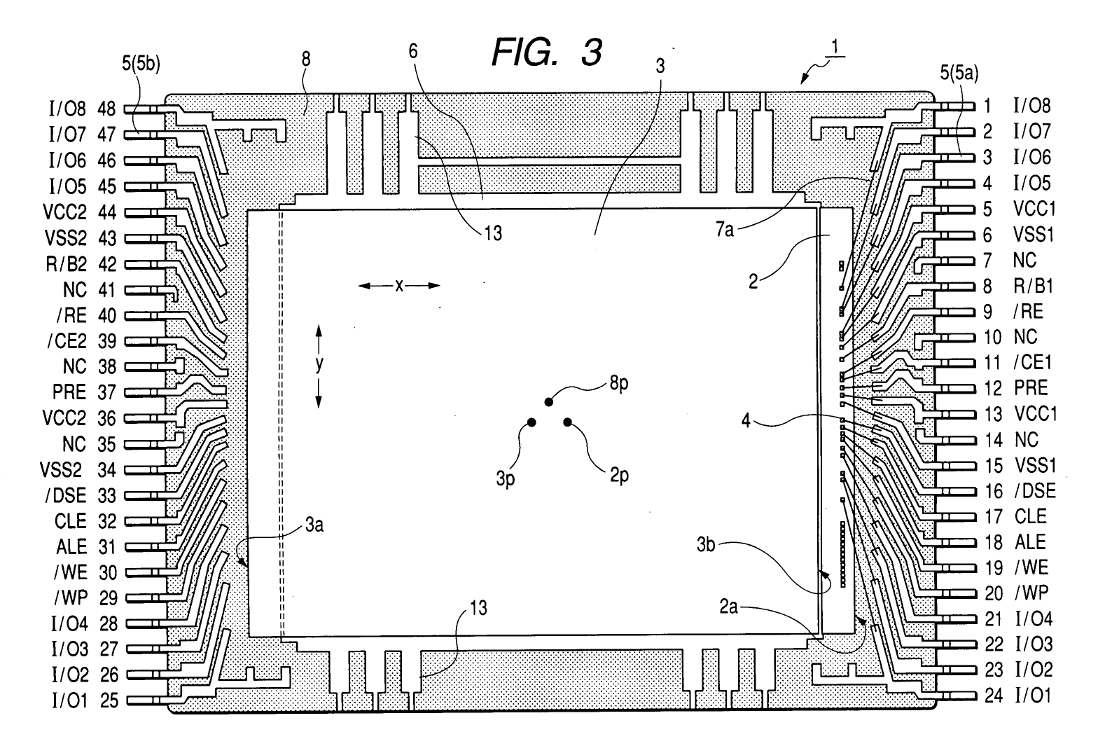

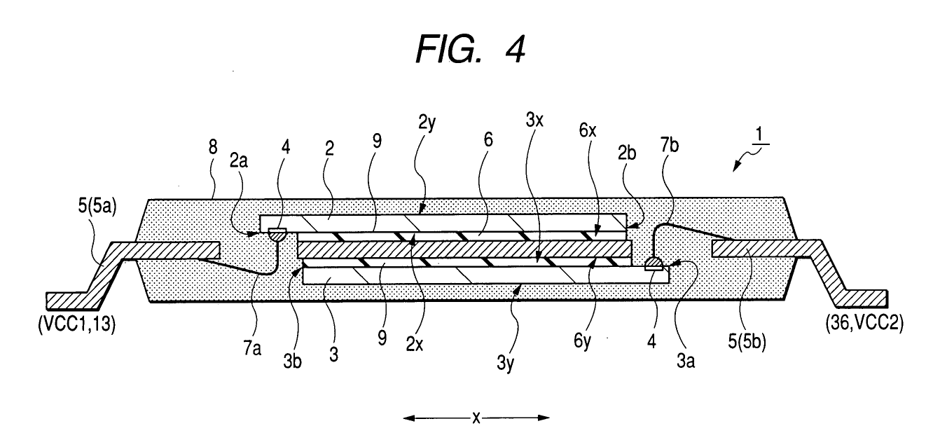

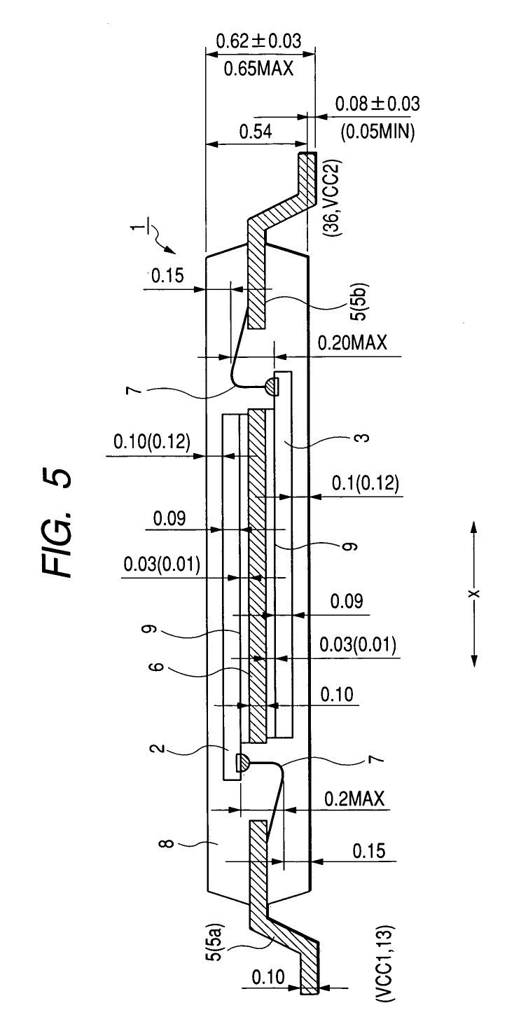

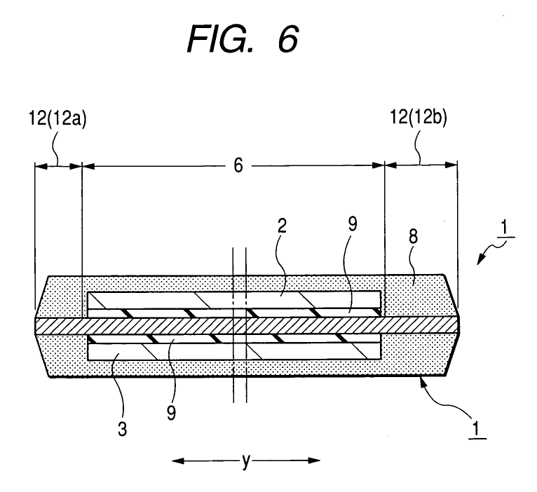

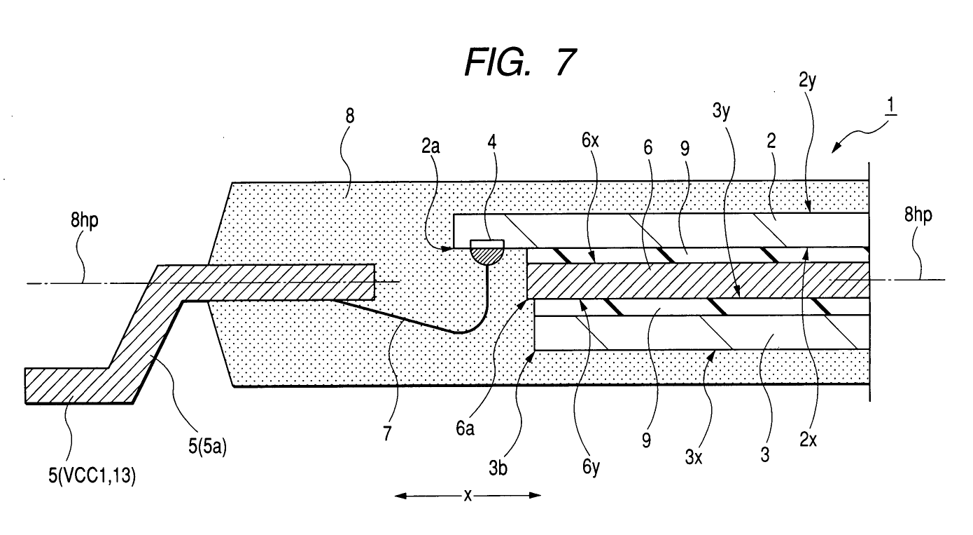

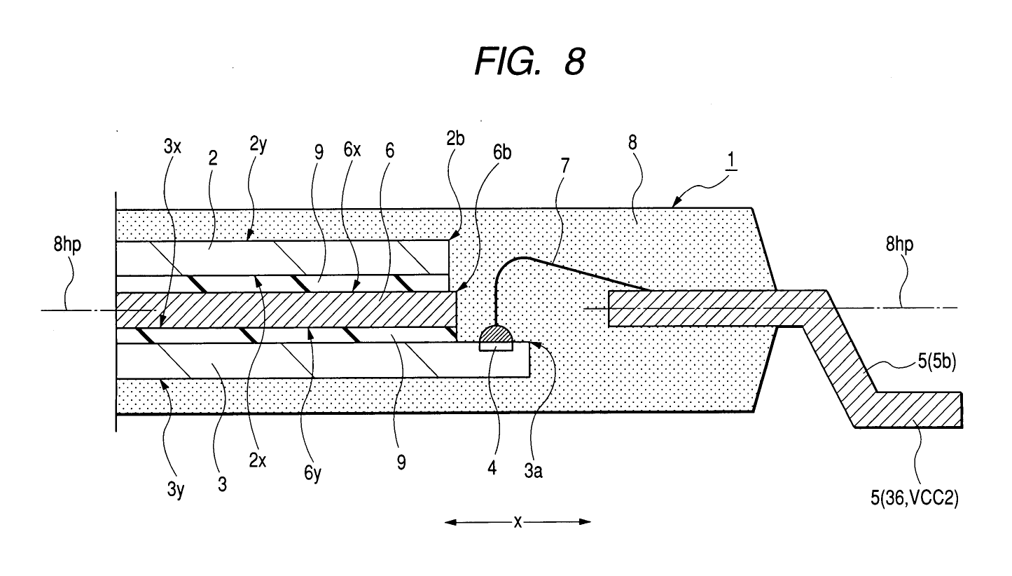

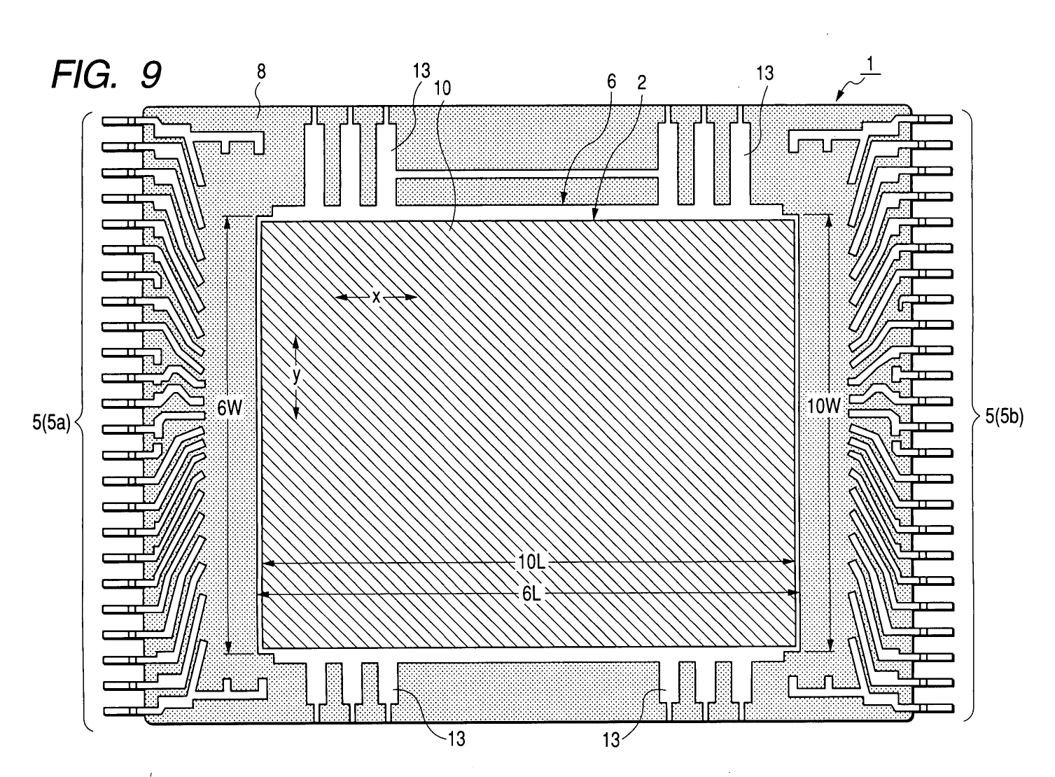

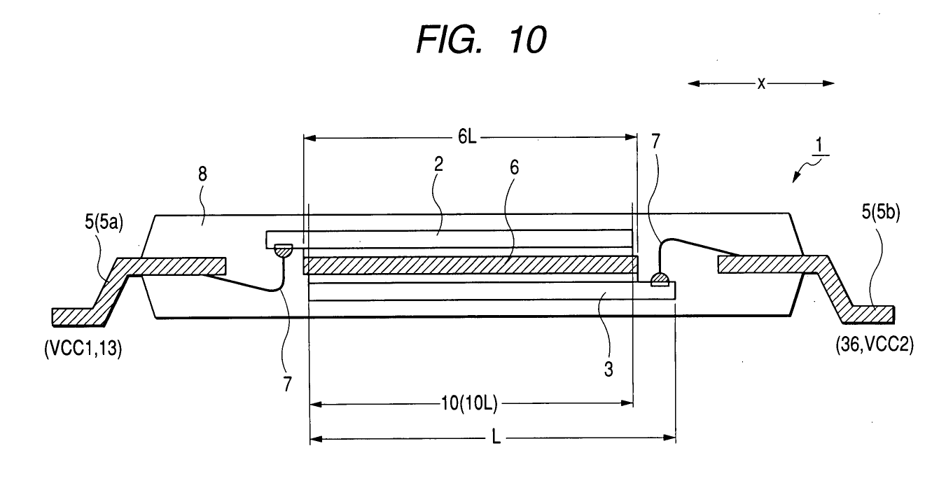

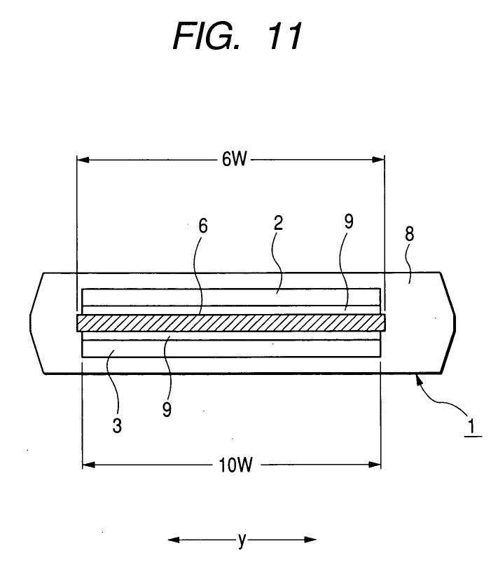

A detailed description of the first embodiment is given with reference to FIGS. 1 to 11. FIG. 1 is a schematic plan view (top view) showing the external structure of a semiconductor device according to a first embodiment of the present invention. FIG. 2 is a schematic plan view (top view) showing the internal structure of the semiconductor device. FIG. 3 is a schematic bottom view showing the internal structure of the semiconductor device. FIG. 4 is a schematic sectional view taken along the x direction of the semiconductor device. FIG. 5 shows the dimensions of various parts of what is shown in FIG. 4. FIG. 6 is a schematic sectional view taken along the y direction of the semiconductor device. FIG. 7 is a schematic enlarged sectional view of part (the left half) of what is shown in FIG. 4. FIG. 8 is a schematic enlarged sectional view of part (the right half) of what is shown in FIG. 4. FIG. 9 is a schematic plan view showing the internal structure of FIG. 2 in a partially omitted form. FIG. 10 is a schematic plan view showing the relation between an overlapping area of two semiconductor chips and a die pad. FIG. 11 is a schematic plan view showing the relation between an overlapping area of two semiconductor chips and a die pad.

It should be noted that the leads shown on the left in FIG. 2 are those shown on the right in FIG. 3 and the leads shown on the right in FIG. 2 are those shown on the left in FIG. 3.

As illustrated in FIGS. 2 to 4, a semiconductor device 1 according to the first embodiment has a package structure which includes: two semiconductor chips 2, 3; a first lead group consisting of plural leads 5 (5a); a second lead group consisting of plural leads 5 (5b); plural bonding wires 7a, 7b; a die pad 6; plural suspender leads 13; and a resin sealer 8. The semiconductor chips 2 and 3 each have a main surface (first surface, circuit formation surface) 2x, 3x and a reverse surface (second surface) 2y, 3y opposite each other and a die pad 6 lies between the chips with the main surfaces 2x and 3x facing each other.

The flat surfaces of the two semiconductor chips 2 and 3, which cross their thickness direction, are rectangular and dimensionally equal. In the first embodiment, the flat surface is a rectangle of 11.46 mm by 8.31 mm. The two long sides of each of the semiconductor chips 2 and 3, which are opposite each other, extend along the x direction while the two short sides (2a and 2b or 3a and 3b) of each of the semiconductor chips 2 and 3, which are opposite each other, extend along the y direction, which is perpendicular to the x direction in the same plane as the x direction.

For example, the semiconductor chips 2 and 3 each mainly consist of a semiconductor substrate of monocrystal silicon and a multilayer wiring layer formed thereon. For example, a 64-Mb EEPROM (Electrically Erasable Programmable Read Only Memory) called a flash memory is mounted over the main surface (2x, 3x) of each of the semiconductor chips 2 and 3.

Over the main surface 2x of the semiconductor chip 2, plural electrodes (bonding pads) 4 are arranged along a short side 2a, one of its short sides opposite each other (see FIGS. 3 and 4). The plural electrodes 4 are formed over the top wiring layer of the multilayer wiring layer of the semiconductor chip 2. The top wiring layer is covered by a surface protective film (final protective film) above it. The surface protective film has bonding holes which expose the surfaces of the electrodes 4.

Over the main surface 3x of the semiconductor chip 3, plural electrodes (bonding pads) 4 are arranged along a short side 3a, one of its short sides opposite each other (see FIGS. 2 and 4). The plural electrodes 4 are formed over the top wiring layer of the multilayer wiring layer of the semiconductor chip 3. The top wiring layer is covered by a surface protective film (final protective film) above it. The surface protective film has bonding holes which expose the surfaces of the electrodes 4.

The circuit pattern of the flash memory of the semiconductor chip 2 is the same as that of the semiconductor chip 3. The arrangement pattern of the electrodes 4 over the main surface 2x of the semiconductor chip 2 is the same as that of the electrodes 4 over the main surface 3x of the semiconductor chip 3. In other words, the semiconductor chips 2 and 3 are identical in terms of dimensions and functionality.

As shown in FIGS. 1 to 3, the flat surface of the resin sealer 8, which crosses its thickness direction, is rectangular in the first embodiment. Plural leads 5 (5a) are arranged along one of the two short sides, opposite each other, of the resin sealer 8 (in the y direction), and plural leads 5 (5b) are arranged along the other short side (in the y direction).

As shown in FIGS. 2 and 4, the plural leads 5a each have an inner portion which lies inside the resin sealer 8, and an outer portion which is integral with the inner portion and lies outside the resin sealer 8: namely they extend inside and outside the resin sealer 8. The plural leads 5a lie outside the short side 2a of the semiconductor chip 2 and their inner portions are electrically connected with the plural electrodes 4 of the semiconductor chip 2 through the plural bonding wires 7a respectively.

As shown in FIGS. 3 and 4, like the leads 5a, the plural leads 5b each have an inner portion and an outer portion and extend inside and outside the resin sealer 8. The plural leads 5b lie outside the short side 2b of the semiconductor chip 2 and their inner portions are electrically connected with the plural electrodes 4 of the semiconductor chip 3 through the plural bonding wires 7b respectively. The outer portions of the leads 5a and 5b are gull wing leads as a kind of surface mount leads.

The bonding wires 7a and 7b are, for example, gold (Au) wires. One possible wire bonding method is a combination of thermal compression and supersonic vibration.

The number of leads 5a or 5b is, for example, 24 and each lead 5 is identified by a terminal name as follows:
VCC (1, 2) represents a power terminal whose potential is fixed at a first reference level (for example, 5 V);
VSS (1, 2) represents a power terminal whose potential is fixed at a second reference level (for example, 0 V) lower than the first reference level;
I/O1 to I/O8 represent data input/output terminals.
/WP represents a write protect terminal;
/WE represents a write enable terminal;
ALE represents an address latch enable terminal;
CLE represents a command latch enable terminal;
/DSE represents a deep standby enable terminal;
NC represents a terminal not used;
PRE represents a power-on read enable terminal;
/CE (1, 2) represents a chip enable terminal;
/RE represents a read enable terminal; and
R/B (1, 2) represents a ready/busy output terminal.

As shown in FIG. 4, the die pad 6 has a first surface 6x and a second surface 6y which are opposite each other and the main surface 2x of the semiconductor chip 2 is bonded to the first surface 6x through an adhesive agent (coating) 9 and the main surface 3x of the semiconductor chip 3 is bonded to the second surface 6y.

The semiconductor chips 2 and 3 are bonded to the die pad 6 in a staggered manner that their main surfaces (2x, 3x) face each other with one short side 2a of the first semiconductor chip 2 and the other short side 3b of the semiconductor chip 3 being located near the leads 5a and the plural electrodes 4 of the semiconductor chip 2 being located more outward than the other short side 3b of the semiconductor chip 3 and the plural electrodes 4 of the second semiconductor chip 3 being located more outward than the other short side 2b of the semiconductor chip 2, namely in a way that the one short side 2a of the semiconductor chip 2 and the one short side 3a of the semiconductor chip 3 are most remote from each other (in the x direction in the first embodiment).

The semiconductor chips 2, 3, the inner portions of the plural leads 5, the die pad 6, the plural suspender leads 13 and the plural bonding wires 7a, 7b and so on are sealed by the resin sealer 8. In order to reduce stress, the resin sealer 8 is made of biphenyl resin to which a phenyl curing agent, silicone rubber and filler are added. The resin sealer 8 is formed by a transfer molding process which is suitable for mass production. In the transfer molding process, which uses a mold die with a pot, runner, resin injection gate, cavity, etc., resin is injected from the pot through the runner and resin injection gate into the cavity to form a resin sealer.

As shown in FIG. 5, the dimensions of various elements are as follows:
the thickness of the semiconductor chips 2 and 3 is 0.09 mm or so;
the thickness of the adhesive agent coating 9 is 0.01 mm or so;
the thickness of the leads 5 (5a, 5b) and the die pad 6 is 0.1 mm or so;
the loop height of the bonding wires 7a, 7b (height from the semiconductor chip bonding plane to the wire top) is 0.2 mm or so;
the thickness of the resin sealer 8 is 0.54 mm or so;
the thickness of the resin over the reverse surface 2y of the semiconductor chip 2 and the thickness of the resin over the reverse surface 3y of the semiconductor chip 3 are 0.1 mm or so;
the distance from the top of the bonding wire 7a to the lower surface (mounting surface, reverse surface) of the resin sealer 8 and the distance from the top of the bonding wire 7b to the upper surface (main surface, front surface) of the resin sealer 8 are each 0.15 mm or so;
the distance from the upper surface of the resin sealer 8 to the lead 5 mounting surface (soldering plane) is 0.62 mm or so; and
the distance from the lower surface of the resin sealer 8 to the lead 5 mounting surface (soldering plane) is 0.08 mm or so.

As shown in FIGS. 2 and 3, the flat surface of the die pad 6, which crosses its thickness direction, is rectangular in this embodiment. Plural leads 5 are arranged along the two short sides of the die pad 6, which are opposite each other, and plural suspender leads 13 are connected along the two long sides of the die pad 6, which are opposite each other. The suspender leads 13 are integral with the die pad 6.

As shown in FIGS. 7 and 8, the inner portions of the leads 5 (5a, 5b) and the die pad 6 are at the same height level in the thickness direction of the resin sealer 8. The center of the thickness of the inner portion of each of the leads 5 lies within the thickness of the die pad 6. The inner portions of the leads 5 and the die pad 6 lie in the center 8hp of the thickness of the resin sealer 8. The center 8hp of the thickness of the resin sealer 8 lies within the thickness of each of the inner portions of the leads 5 and the die pad 6.

The loop height of the bonding wires 7a is lower than the reverse surface 3y of the semiconductor chip 3 in the thickness direction of the resin sealer 8 as shown in FIG. 7, and the loop height of the bonding wires 7b is lower than the reverse surface 2y of the semiconductor chip 2 in the thickness direction of the resin sealer 8 as shown in FIG. 8.

As shown in FIGS. 2 and 3, the suspender leads 13 are straight or not bent in the thickness direction of the resin sealer 8 and lie at the same height as the leads 5 and the die pad 6 in the thickness direction of the resin sealer 8.

In FIGS. 2 and 3, 8p represents the center point of the flat surface of the resin sealer 8 as the intersection of its two diagonals; 2p represents the center point of the main surface 2x of the semiconductor chip 2 as the intersection of its two diagonals; and 3p represents the center point of the main surface 3x of the semiconductor chip 3 as the intersection of its two diagonals. The semiconductor chips 2 and 3 are stacked with their center points (2p, 3p) spaced away from each other along the x direction and their main surfaces facing each other with the die pad 6 between them. The semiconductor chips 2 and 3 are resin-sealed with their center points (2p, 3p) away from the center point 8p of the resin sealer 8 along the y direction.

As shown in FIGS. 7 and 8, in the first embodiment, the semiconductor chips 2 and 3 are bonded to the die pad 6 with their main surfaces (2x, 3x) facing each other with the die pad 6 between them. In this structure, the loop height of the bonding wires 7a is absorbed by the thicknesses of the adhesive agent coating 9, semiconductor chip 3 and die pad 6; and the loop height of the bonding wires 7b is absorbed by the thicknesses of the adhesive agent 9, semiconductor chip 2 and die pad 6. This means that the resin sealer thickness over the reverse surface 2y of the semiconductor chip 2 and the resin sealer thickness over the reverse surface 3y of the semiconductor chip 3 (namely the overall thickness of the resin sealer 8) can be reduced and the overall thickness of the semiconductor device 1 can be thus reduced.

When the semiconductor chips 2, 3, two adhesive agent coatings 9 and die pad 6 constitute a laminate, the die pad 6 symmetrically divides the thickness of the laminate into an upper half and a lower half. Hence, the center of the thickness of the laminate (die pad 6) and the inner portions of the leads 5 can lie in the center 8hp of the thickness of the resin sealer 8 without the need for bending the suspender leads 13.

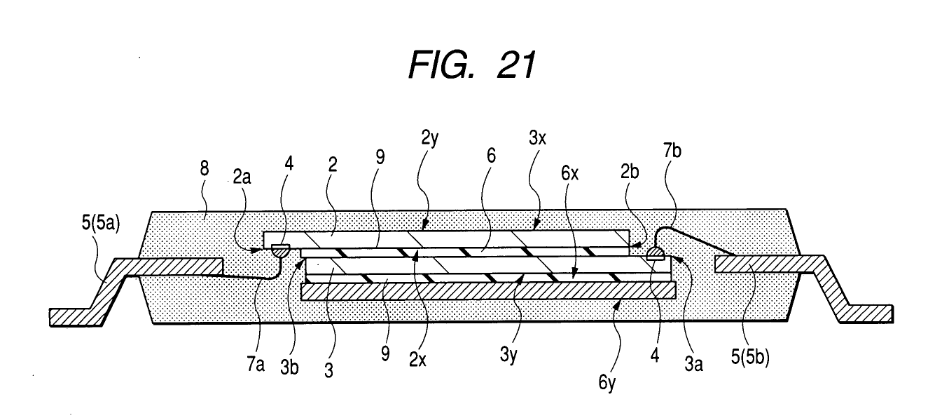

As the resin sealer 8 becomes thinner, the resin thickness over and under the inner portions of the leads 5 in the thickness direction also becomes smaller; so taking the fastening strength of the leads 5 into consideration, it is desirable that the inner portions of the leads 5 lie in the center of the thickness of the resin sealer 8 and the outer portions of the leads 5 protrude from the center of the thickness of the resin sealer 8. On the other hand, when the resin sealer 8 is formed by transfer molding, because voids should be reduced in order to prevent an unfavorable influence on the quality of the resin sealer 8, it is desirable that a laminate which includes the two semiconductor chips (2, 3), two adhesive agent coatings 9, and die pad 6 be resin-sealed with the center of the thickness of the laminate coincident with the center of the thickness of the mold die cavity, namely coincident with the center of the thickness of the resin sealer 8. When the fastening strength of the leads 5 and the need for reduction of voids are taken into consideration as mentioned above, according to the semiconductor device previously conceived by the inventors, the suspender leads must be bent to make the height level of the die pad 6 and that of the inner portions of the leads 5 different, or offset them from each other in the thickness direction of the resin sealer 8 as shown in FIG. 21. On the other hand, according to the first embodiment of the present invention, since the die pad 6 symmetrically divides the laminate into an upper half and a lower half as mentioned above, it is no longer necessary to offset the die pad 6 and the inner portions of the leads 5 from each other in the thickness direction of the resin sealer 8 by bending the suspender leads. Consequently, no deterioration in the strength of the suspender leads due to their bending occurs and in the resin sealing process, positional unstableness of the die pad 6 due to movement of resin injected into the mold die cavity is prevented. This eliminates the possibility that the semiconductor chips (2, 3), bonding wires (7a, 7b) and so on are exposed or not covered by the resin sealer 8 (location trouble) Therefore, it is possible to provide the semiconductor device 1 which assures a high production yield

It is also possible to decrease the thickness of the semiconductor device 1 by using a long, narrow support lead as a chip bearer instead of the die pad 6. In this case, the two semiconductor chips are stacked with their main surfaces facing each other with the support lead between them.

However, when the support lead is used as the chip bearer, spots which are not filled with resin, namely voids, will be more likely to be generated between the semiconductor chips. In order to prevent generation of voids, it is desirable that the chip bearer be larger than an area where the two semiconductor chips overlap (overlapping area). In the first embodiment, the size (6L×6W) of the die pad 6 is larger than the size (10L×10W) of the overlapping area 10 of the semiconductor chips 2 and 3 as shown in FIGS. 9 to 11. Here, it should be noted that, in order to permit wire bonding, the size of the die pad 6 must be determined so as for its sides 6a and 6b to lie more inward than the electrodes 4 of the semiconductor chips.

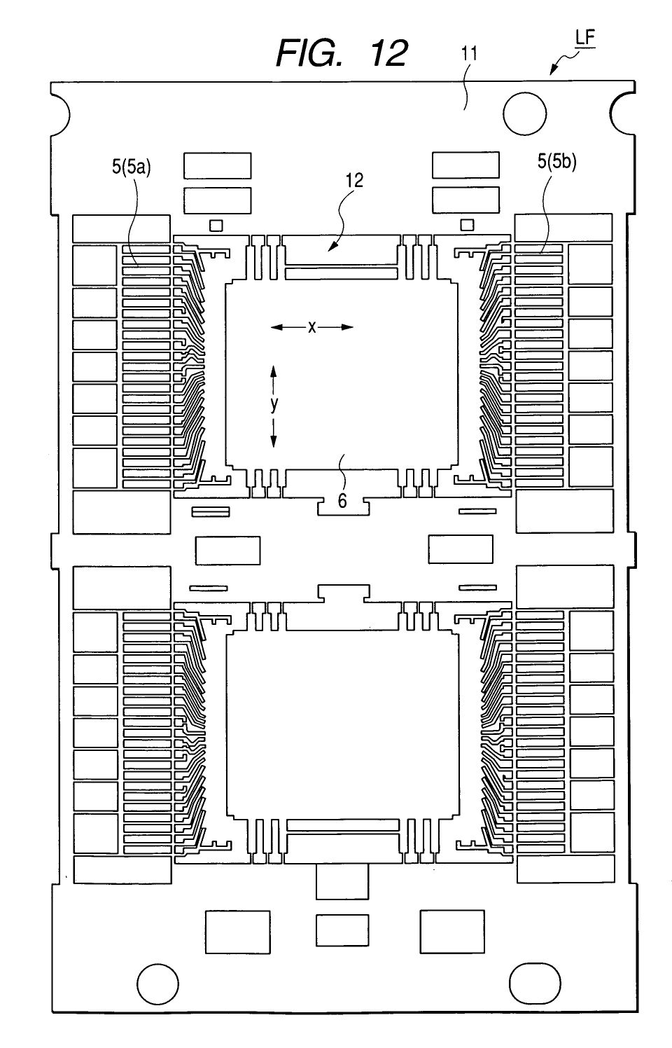

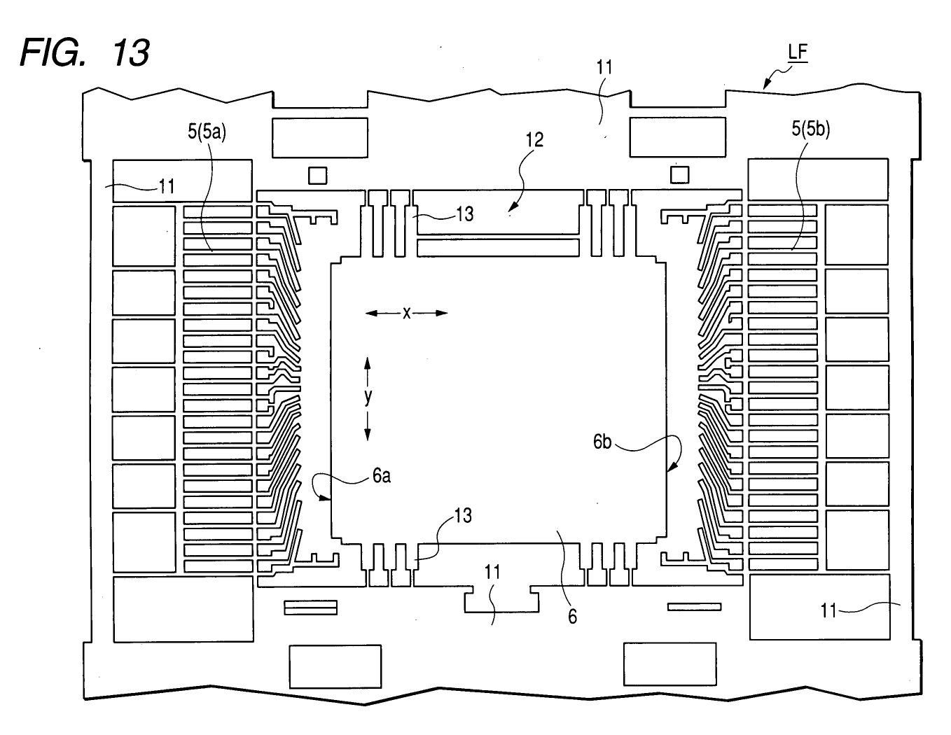

Next, a lead frame which is used in the process of manufacturing the semiconductor device 1 will be described referring to FIGS. 12 and 13. FIG. 12 is a fragmentary schematic plan view showing the lead frame and FIG. 13 is a schematic enlarged sectional view of part of what is shown in FIG. 12. For increased productivity, an actual lead frame has two rows of product formation areas (device formation areas) . Here, however, for simple illustration, FIG. 12 shows an upper product formation area and a lower one.

As shown in FIGS. 12 and 13, a lead frame LF has plural leads 5a, plural leads 5b, a die pad 6 and plural suspender leads 13 inside a product formation area 12 marked off by a frame body 11. The die pad 6 lies in the center of the product formation area 12. The plural leads 5a are arranged outside one short side 6a of the die pad 6 and their ends opposite to the ends facing the die pad 6 are integral with the frame body 11. The leads 5b are arranged outside the other short side 6b of the die pad 6 and their ends opposite to the ends facing the die pad 6 are integral with the frame body 11. Plural suspender leads 13 are connected integrally with one long side of the die pad 6 and also integral with the frame body 11. Plural suspender leads 13 are connected integrally with the other long side of the die pad 6 and also integral with the frame body 11. The plural suspender leads 13 are straight or not bent in the thickness direction of the lead frame LF.

The plural leads 5a each consist of an inner portion (which is sealed or inside the resin sealer) and an outer portion (which is outside the resin sealer) and are interconnected through a tie bar (dam bar). The plural leads 5b each consist of an inner portion (which is sealed or inside the resin sealer) and an outer portion (which is outside the resin sealer) and are interconnected through a tie bar (dam bar).

The lead frame LF is made by etching or doing press work on a plate of iron-nickel (Fe—Ni) alloy or copper (Cu) or copper alloy to form a prescribed lead pattern. In the first embodiment, an offset process that makes the height level of the die pad 6 and that of the lead 5 inner portions different in the plate thickness direction of the lead frame LF is not carried out on the lead frame LF.

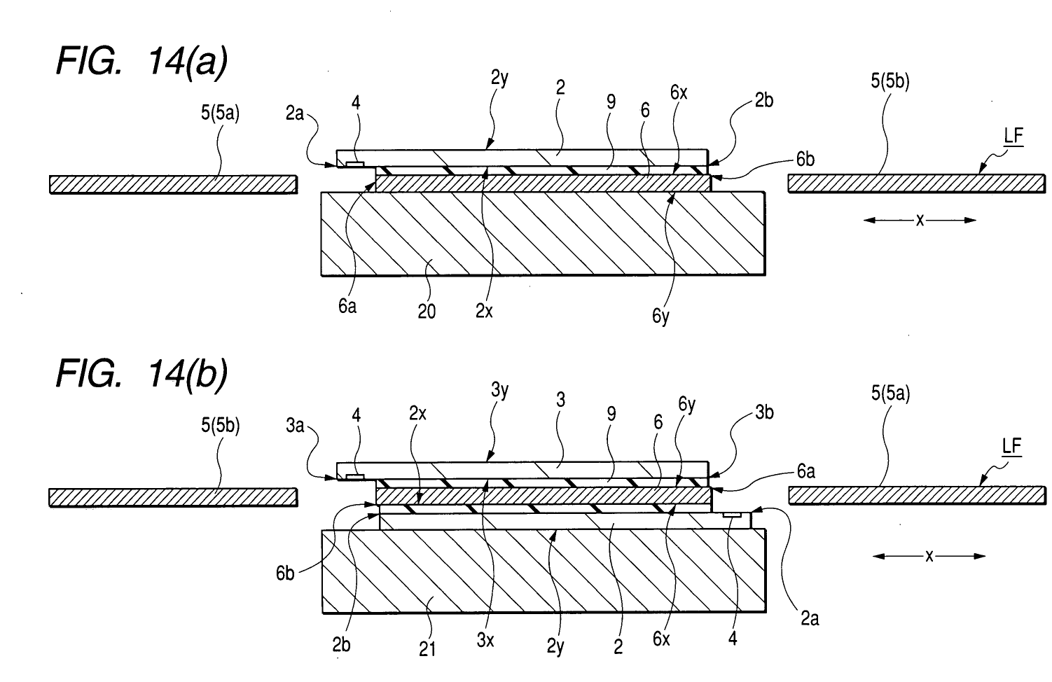

Next, the method of manufacturing the semiconductor device 1 will be explained referring to FIGS. 14 to 18.

FIGS. 14 to 18 concern the manufacture of the semiconductor device according to the first embodiment, where:

FIGS. 14(a) and 14(b) are schematic sectional views showing a die bonding process, in which FIG. 14(a) shows a first die bonding step and FIG. 14(b) shows a second die bonding step;

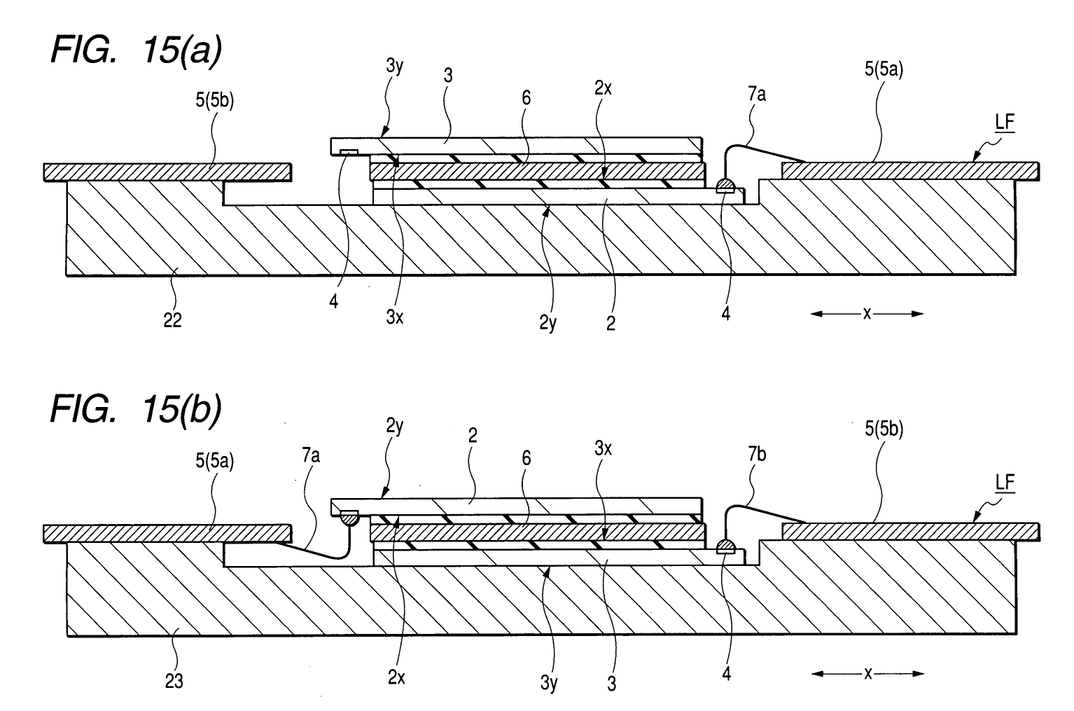

FIGS. 15(a) and 14(b) are schematic sectional views showing a wire bonding process, in which FIG. 15(a) shows a first wire bonding step and FIG. 15(b) shows a second wire bonding step;

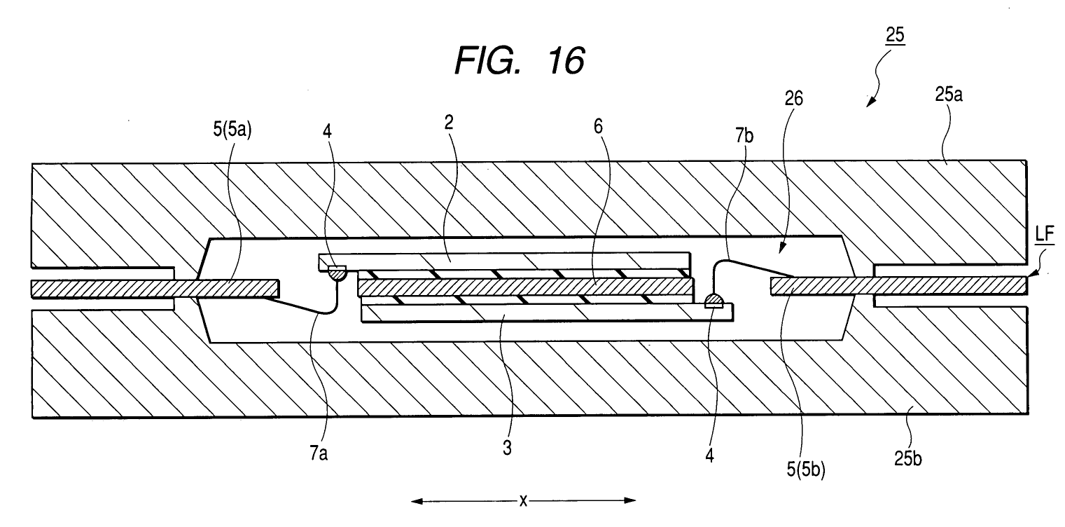

FIG. 16 is a schematic sectional view (taken along the x direction) showing a lead frame in place in a mold die in the molding process;

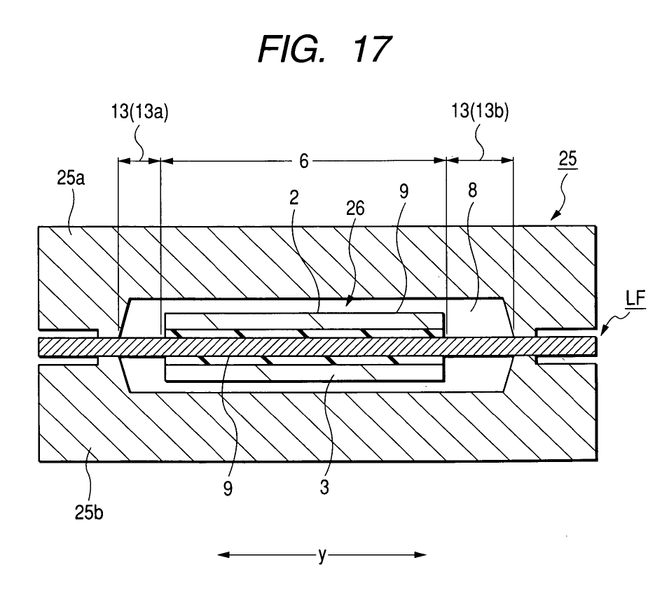

FIG. 17 is a schematic sectional view (taken along the y direction) showing a lead frame in place in a mold die in the molding process;

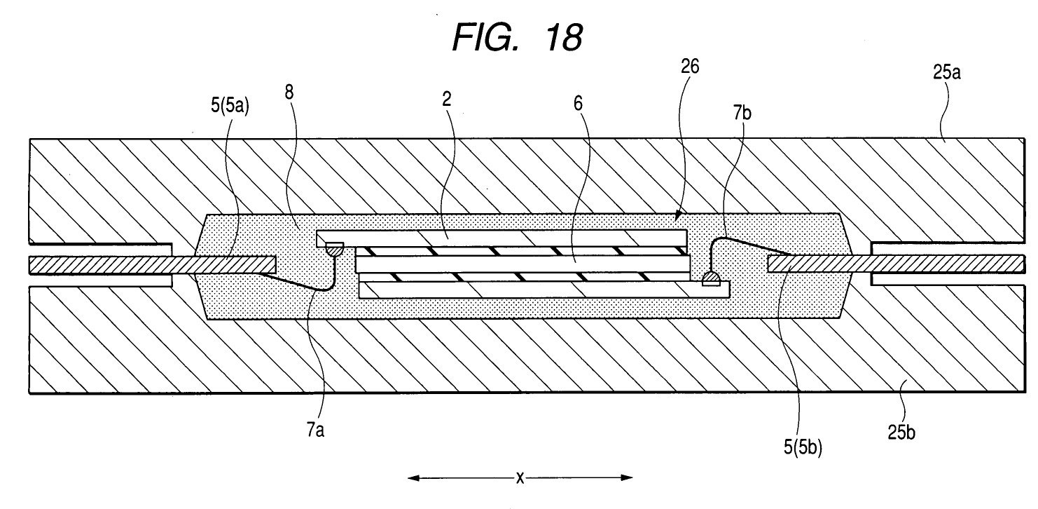

FIG. 18 is a schematic sectional view showing resin injected in the mold die cavity (formed resin sealer) in the molding process.

First, one semiconductor chip 2 is bonded to the die pad 6 in the lead frame LF. Fixing of the semiconductor chip 2 to the die pad 6 is carried out as illustrated in FIG. 14(a): the die pad 6 is placed on a heat stage 20 and an adhesive agent is coated over a first surface 6x of the die pad 6, then the semiconductor chip 2 is pressed against the die pad 6 by means of a pressure collet with the main surface 2x of the semiconductor chip 2 facing the first surface 6x of the die pad 6. In this pressure contact process, the die pad 6 is heated by the heat stage 20 and the semiconductor chip 2 is heated by the pressure collet. The adhesive agent 9 may be thermosetting resin bond.

In the above process of fixing the semiconductor chip 2, one short side 2a of the semiconductor chip 2 should be near the leads 5a and plural electrodes 4 of the semiconductor chip 2 should be located more outward than one short side 6a of the die pad 6.

Next, the other semiconductor chip 3 is bonded to the die pad 6 in the lead frame LF. Fixing of the semiconductor chip 3 to the die pad 6 is carried out as follows: the lead frame LF is turned upside down and consequently the second surface 6y of the die pad 6 is up as illustrated in FIG. 14(b), and the die pad 6 is placed on a heat stage 21 and an adhesive agent 9 is coated over a second surface 6y of the die pad 6, then the semiconductor chip 3 is pressed against the die pad 6 by means of a pressure collet with the main surface 3x of the semiconductor chip 3 facing the second surface 6y of the die pad 6. In this pressure contact process, the die pad 6 is heated by the heat stage 21 and the semiconductor chip 3 is heated by the pressure collet. The adhesive agent 9 may be thermosetting resin bond.

In the above process of fixing the semiconductor chip 3, one short side 3a of the semiconductor chip 3 should be near the leads 5b and plural electrodes 4 of the semiconductor chip 3 should be located more outward than the other short side 6b of the die pad 6.

Thus, the semiconductor chips 2 and 3 are stacked while the one short side 2a of the semiconductor chip 2 is near the leads 5a, the one short side 3a of the semiconductor chip 3 is near the leads 5b, the electrodes 4 of the semiconductor chip 2 are located more outward than the other short side 3b of the semiconductor chip 3 and the one short side 6a of the die pad 6, and the electrodes 4 of the semiconductor chip 3 are located more outward than the other short side 2b of the semiconductor chip 2 and the other short side 6b of the die pad 6.

Next, the electrodes 4 of the semiconductor chip 2 are electrically connected with the inner portions of the leads 5a through bonding wires 7a. This electrical connection is made as follows: as illustrated in FIG. 15(a), with the reverse surface 3y of the semiconductor chip 3 up, the semiconductor chip 2 and the inner portions of the leads 5a are placed on the heat stage 22 and heated by the heat stage 22. The bonding wires 7a are, for example, Au wires. The connection method for the bonding wires 7a may be a combination of thermal compression and supersonic vibration.

Next, the electrodes 4 of the semiconductor chip 3 are electrically connected with the inner portions of the leads 5b through bonding wires 7b. This electrical connection is made as follows: as illustrated in FIG. 15(b), with the reverse surface 2y of the semiconductor chip 2 up, the semiconductor chip 2 and the inner portions of the leads 5a are placed on the heat stage 23 and heated by the heat stage 23. The bonding wires 7b are, for example, Au wires. The connection method for the bonding wires 7b may be a combination of thermal compression and supersonic vibration.

Next, the semiconductor chips 2, 3, the inner portions of the plural leads 5 (5a, 5b), the die pad 6, the plural bonding wires 7a, 7b and plural suspender leads 13 are resin-sealed to form a resin sealer 8. The process of forming the resin sealer 8 is as follows. First, as illustrated in FIGS. 16 and 17, the lead frame LF is positioned between an upper mold 25a and a lower mold 25b of a mold die 25. The position of the lead frame LF should be such that the semiconductor chips 2, 3, the inner portions of the plural leads 5 (5a, 5b), the die pad 6, the plural bonding wires 7a, 7b and the plural suspender leads 13 are inside a cavity 26 of the mold die 25. In this process, the center (die pad 6) of the thickness of the laminate including the semiconductor chips 2, 3, two adhesive agent coatings 9 and the die pad 6 should lie in the center of the thickness of the cavity 26. Also, the inner portions of the leads 5 should lie in the center of the thickness of the cavity 26. Then, as illustrated in FIG. 18, thermosetting resin is injected into the cavity 26. The resin sealer 8 is thus formed.

In this process, since the suspender leads 13 are not bent, the risk that the semiconductor chips 2 and 3 might be exposed or not covered by the resin sealer 8 is prevented.

Next, the lead frame LF is taken out of the mold die 25 and curing is done to cure the resin of the resin sealer 8. Then, the tie bars connected with the leads 5a and 5b are cut and the outer portions of the leads 5a and 5b are plated. After that, the leads 5a and 5b are cut off the frame body 11 of the lead frame LF and the outer portions of the leads 5a and 5b are shaped into a pattern suitable for the surface mount type, for example, gull wings; then the suspender leads 13 are cut off the frame body 11 of the lead frame LF. The semiconductor device 1 as shown in FIGS. 1 to 4 is almost completed in this way.

In this way, a thin semiconductor device 1 which assures a high production yield is provided according to the first embodiment.

### Second Embodiment

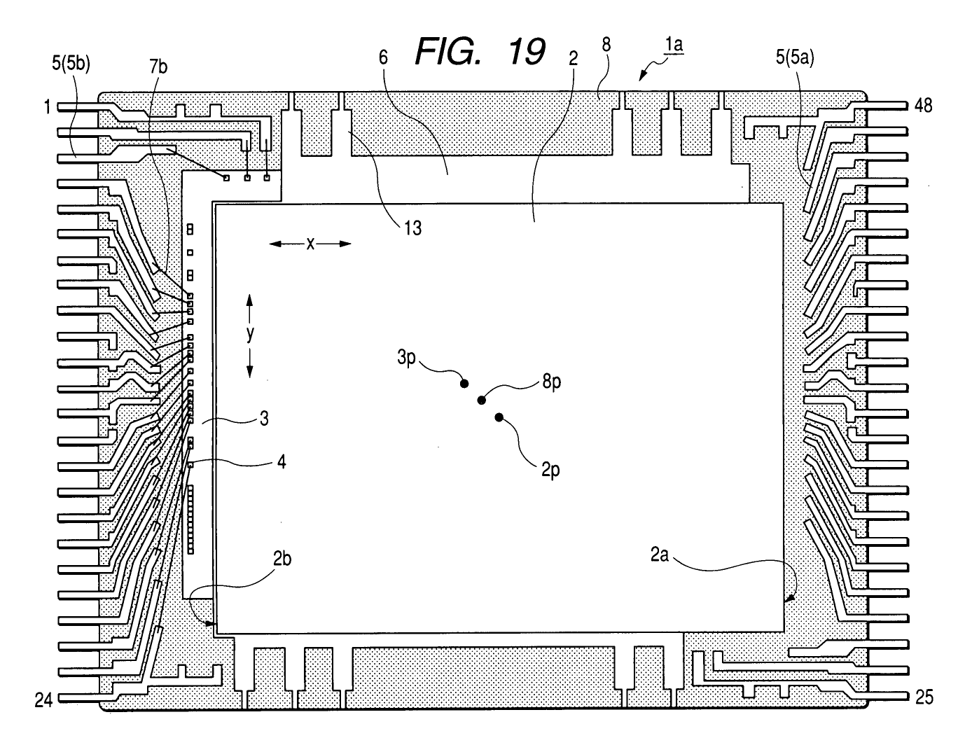

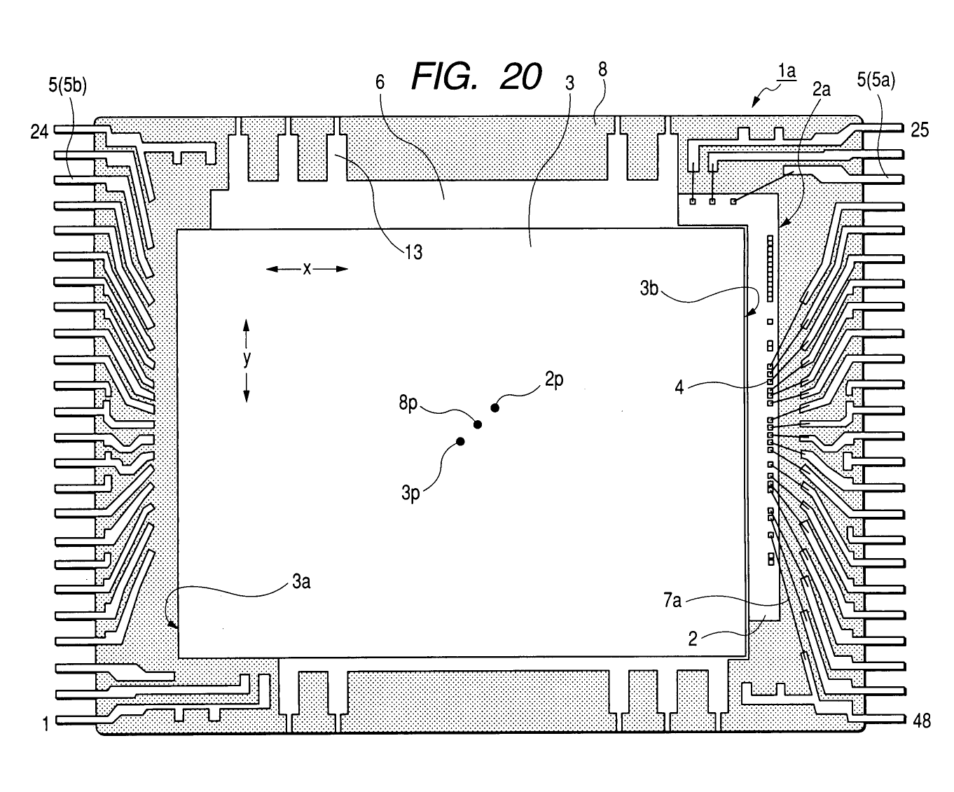

FIGS. 19 and 20 concern a semiconductor device according to the second embodiment of the present invention.

FIG. 19 is a schematic plan view (top view) showing the internal structure of the semiconductor device; and

FIG. 20 is a schematic bottom view showing the internal structure of the semiconductor device.

As apparent from FIGS. 19 and 20, basically a semiconductor device 1a according to the second embodiment is the same as the semiconductor device 1 according to the first embodiment except the following points.

In the semiconductor chips 2 and 3, plural electrodes 4 are also arranged along one of the two long sides opposite each other. The electrodes 4 arranged along the one long side of the semiconductor chip 2 are electrically connected with the inner portions of the leads 5a through bonding wires 7a and also the electrodes 4 arranged along the one long side of the semiconductor chip 3 are electrically connected with the inner portions of the leads 5b through bonding wires 7b.

The semiconductor chips 2 and 3 are stacked in a staggered manner as follows. The electrodes 4 arranged along one short side 2a of the semiconductor chip 2 are located more outward than the other short side 3b of the semiconductor chip 3 and the electrodes 4 arranged along one short side 3a of the semiconductor chip 3 are located more outward than the other short side 2b of the semiconductor chip 2, namely in a way that the one short side 2a of the semiconductor chip 2 and the one short side 3a of the semiconductor chip 3 are most remote from each other (in the x direction in the second embodiment) In addition, the electrodes 4 arranged along one long side of the semiconductor chip 2 are located more outward than the other long side of the semiconductor chip 3 and the electrodes 4 arranged along one long side of the semiconductor chip 3 are located more outward than the other long side of the semiconductor chip 2, namely in a way that the one long side of the semiconductor chip 2 and the one long side of the semiconductor chip 3 are most remote from each other (in the y direction in the second embodiment).

The semiconductor device 1a thus structured also brings about the same effects as in the first embodiment.

So far, preferred embodiments of the invention made by the inventors have been concretely described. However, obviously the present invention is not limited to the above embodiments but may be embodied in other various forms without departing from the scope and spirit thereof.

For example, the present invention may be applied to TSOP semiconductor device Type 1.

1. A semiconductor device comprising:
first and second semiconductor chips each having first and second surfaces opposite each other and a plurality of electrodes arranged over the first surface;
a plurality of first leads each having an inner portion and an outer portion, the inner portions being electrically connected with the plural electrodes of the first semiconductor chip through a plurality of first bonding wires respectively;
a plurality of second leads each having an inner portion and an outer portion, the inner portions being electrically connected with the plural electrodes of the second semiconductor chip through a plurality of second bonding wires respectively;
a die pad having first and second surfaces opposite each other, the first semiconductor chip's first surface being bonded to the first surface and the second semiconductor chip's first surface being bonded to the second surface; and
a resin sealer which seals the first and second semiconductor chips, the inner portions of the plural first and second leads, the plural first and second bonding wires, and the die pad,
wherein the inner portions of the plural first and second leads and the die pad lie at the same height level in a thickness direction of the resin sealer.

2. The semiconductor device according to claim 1, wherein a center of a thickness of each of the inner portions of the first and second leads lies within a thickness of the die pad.

3. The semiconductor device according to claim 1, wherein the inner portions of the first and second leads and the die pad lie in a center of a thickness of the resin sealer.

4. The semiconductor device according to claim 1, wherein the center of the thickness of the resin sealer lies within the thickness of each of the inner portions of the first and second leads and the die pad.

5. The semiconductor device according to claim 1, further having a suspender lead integral with the die pad, wherein the suspender lead is straight or not bent in the thickness direction of the resin sealer and lies at the same height level as the inner portions of the first and second leads in the thickness direction of the resin sealer.

6. The semiconductor device according to claim 1,
wherein a loop height of the first bonding wires is lower than a second surface of the first semiconductor chip in the thickness direction of the resin sealer; and
wherein a loop height of the second bonding wires is lower than a second surface of the second semiconductor chip in the thickness direction of the resin sealer.

7. The semiconductor device according to claim 1,
wherein the first and the second semiconductor chips each have first and second sides opposite each other;
wherein the plural electrodes of the first semiconductor chip are arranged along the first side of the first semiconductor chip;
wherein the plural electrodes of the second semiconductor chip are arranged along the first side of the second semiconductor chip;
wherein the plural first leads are arranged along the first side of the first semiconductor chip;
wherein the plural second leads are arranged along the second side of the first semiconductor chip; and
wherein the first and second semiconductor chips are bonded to the die pad in a staggered manner that their first surfaces face each other with the first side of the first semiconductor chip and the second side of the second semiconductor chip being located near the first leads, the plural electrodes of the first semiconductor chip being located more outward than the second side of the second semiconductor chip and the plural electrodes of the second semiconductor chip being located more outward than the second side of the first semiconductor chip.

8. A semiconductor device comprising:
first and second semiconductor chips each having first and second surfaces opposite each other and a plurality of electrodes arranged over the first surface;
a plurality of first leads each having an inner portion and an outer portion, the inner portions being electrically connected with the plural electrodes of the first semiconductor chip through a plurality of first bonding wires respectively;
a plurality of second leads each having an inner portion and an outer portion, the inner portions being electrically connected with the plural electrodes of the second semiconductor chip through a plurality of second bonding wires respectively;
a die pad having first and second surfaces opposite each other, the first semiconductor chip's first surface being bonded to the first surface and the second semiconductor chip's first surface being bonded to the second surface; and
a resin sealer which seals the first and second semiconductor chips, the inner portions of the plural first and second leads, the plural first and second bonding wires, and the die pad,
wherein the die pad is larger than an overlapping area in which the first semiconductor chip and the second semiconductor chip overlap.

9. The semiconductor device according to claim 8,
wherein the first and the second semiconductor chips each have first and second sides opposite each other;
wherein the plural electrodes of the first semiconductor chip are arranged along the first side of the first semiconductor chip;
wherein the plural electrodes of the second semiconductor chip are arranged along the first side of the second semiconductor chip;
wherein the plural first leads are arranged along the first side of the first semiconductor chip;
wherein the plural second leads are arranged along the second side of the first semiconductor chip; and
wherein the first and second semiconductor chips are bonded to the die pad in a staggered manner that their first surfaces face each other with the first side of the first semiconductor chip and the second side of the second semiconductor chip being located near the first leads, the plural electrodes of the first semiconductor chip being located more outward than the second side of the second semiconductor chip and the plural electrodes of the second semiconductor chip being located more outward than the second side of the first semiconductor chip.

10. A semiconductor device comprising:
first and second semiconductor chips each having first and second surfaces opposite each other and a plurality of electrodes arranged over the first surface;
a plurality of first leads each having an inner portion and an outer portion, the inner portions being electrically connected with the plural electrodes of the first semiconductor chip through a plurality of first bonding wires respectively;
a plurality of second leads each having an inner portion and an outer portion, the inner portions being electrically connected with the plural electrodes of the second semiconductor chip through a plurality of second bonding wires respectively;
a die pad having first and second surfaces opposite each other, the first semiconductor chip's first surface being bonded to the first surface and the second semiconductor chip's first surface being bonded to the second surface; and
a resin sealer which seals the first and second semiconductor chips, the inner portions of the plural first and second leads, the plural first and second bonding wires, and the die pad,
wherein the inner portions of the plural first and second leads and the die pad lie at the same height level in a thickness direction of the resin sealer, and
wherein the die pad is larger than an overlapping area in which the first semiconductor chip and the second semiconductor chip overlap.

11. The semiconductor device according to claim 10,
wherein the first and the second semiconductor chips each have first and second sides opposite each other;
wherein the plural electrodes of the first semiconductor chip are arranged along the first side of the first semiconductor chip;
wherein the plural electrodes of the second semiconductor chip are arranged along the first side of the second semiconductor chip;
wherein the plural first leads are arranged along the first side of the first semiconductor chip;
wherein the plural second leads are arranged along the second side of the first semiconductor chip; and
wherein the first and second semiconductor chips are bonded to the die pad in a staggered manner that their first surfaces face each other with the first side of the first semiconductor chip and the second side of the second semiconductor chip being located near the first leads, the plural electrodes of the first semiconductor chip being located more outward than the second side of the second semiconductor chip and the plural electrodes of the second semiconductor chip being located more outward than the second side of the first semiconductor chip.

12-13. (canceled).
